(19) United States
(12) Patent Application Publication
(10) Pub. No.: US 2025/0183848 A1
(43) Pub. Date: Jun. 5, 2025

(54) DOHERTY AMPLIFIER CIRCUIT AND SEMICONDUCTOR DEVICE

(71) Applicant: SUMITOMO ELECTRIC DEVICE INNOVATIONS, INC., Yokohama-shi (JP)

(72) Inventor: Takashi SUMIYOSHI, Yokohama-shi (JP)

(73) Assignee: SUMITOMO ELECTRIC DEVICE INNOVATIONS, INC., Yokohama-shi (JP)

(21) Appl. No.: 18/930,265

(22) Filed: Oct. 29, 2024

(30) Foreign Application Priority Data
Nov. 30, 2023 (JP) 2023-203113

(51) Int. Cl. H03F 1/02; H01L 23/66; H03F 1/56; H03F 3/24; H03F 3/60

(52) U.S. Cl. CPC H03F 1/0288; H01L 23/66; H03F 1/56; H03F 3/245; H03F 3/604; H01L 2223/6611; H01L 2223/6655

(57) ABSTRACT

A Doherty amplifier circuit includes a divider configured to divide a received input signal into a first signal and a second signal, a circuit board, a first amplifier amplifying the first signal and output the amplified first signal as a fourth signal, a second amplifier and amplifying the second signal and output the amplified second signal as a fifth signal, a combining node combining the fourth signal and the fifth signal into a combined signal and output the combined signal to an output terminal as an output signal, an open stub, the open stub having an end electrically connected to a path between the divider and the first amplifier, and a first impedance converter, the first impedance converter having a first end electrically connected to the second amplifier and a second end electrically connected to the combining node.

### CROSS REFERENCE TO RELATED APPLICATIONS

This application claims priority based on Japanese Patent Application No. 2023-203113 filed on Nov. 30, 2023, and the entire contents of the Japanese patent application are incorporated herein by reference.

### TECHNICAL FIELD

The present invention relates to a Doherty amplifier circuit and a semiconductor device.

### BACKGROUND ART

There is known an N-way (N is two or more) Doherty amplifier circuit using a main amplifier and two or more peak amplifiers (for example, U.S. Pat. Nos. 8,022,760 and 10601375).

### SUMMARY OF THE INVENTION

A Doherty amplifier circuit according to an embodiment of the present disclosure includes a divider that divides a received input signal into a first signal and a second signal, a circuit board, a first amplifier disposed on the circuit board and that amplifies the first signal and outputs an amplified first signal as a fourth signal, a second amplifier disposed on the circuit board and that amplifies the second signal and outputs an amplified second signal as a fifth signal, a combining node that combines the fourth signal and the fifth signal into a combined signal and outputs the combined signal to an output terminal as an output signal, an open stub disposed on the circuit board, the open stub having an end electrically connected to a path between the divider and the first amplifier, and a first impedance converter disposed on the circuit board, the first impedance converter having a first end electrically connected to the second amplifier and a second end electrically connected to the combining node.

A semiconductor device for a Doherty amplifier circuit according to an embodiment of the present disclosure includes a first input terminal that receives a first signal divided from a received input signal, a second input terminal that receives a second signal divided from the input signal, a first amplifier that amplifies the first signal and outputs an amplified first signal as a fourth signal, a second amplifier that amplifies the second signal and outputs an amplified second signal as a fifth signal, a first output terminal that outputs the fourth signal, a second output terminal that outputs the fifth signal, and a terminal connected to a line between the first input terminal and the first amplifier, the terminal being connectable to an open stub that adjusts a phase of the first signal.

### BRIEF DESCRIPTION OF THE DRAWINGS

FIG. 1 is a block diagram of a Doherty amplifier circuit according to a first embodiment.

FIG. 2 is a plan view of a semiconductor device in the first embodiment.

FIG. 3 is a plan view of a circuit board in the first embodiment.

FIG. 4 is a schematic diagram illustrating the probability for Pout, Pout of each amplifier for Pin, the gain of each amplifier for Pin, and the overall gain for Pin in the first embodiment.

FIG. 5 is a block diagram of a Doherty amplifier circuit in a first comparative example.

FIG. 6 is a plan view of a semiconductor device in the first comparative example.

### DETAILED DESCRIPTION

In the Doherty amplifier circuit, an impedance converter is disposed behind either the main amplifier or the peak amplifier. In order to adjust the phase delay caused by the impedance converter, a phase adjuster is disposed in front of either the main amplifier or the peak amplifier. This results in an increase in size.

An object of the present disclosure is to reduce the size of a Doherty amplifier circuit or a semiconductor device for a Doherty amplifier circuit.

### Description of Embodiments of Present Disclosure

First, the contents of embodiments of the present disclosure will be listed and explained.
(1) A Doherty amplifier circuit according to an embodiment of the present disclosure includes a divider that divides a received input signal into a first signal and a second signal, a circuit board, a first amplifier disposed on the circuit board and that amplifies the first signal and outputs an amplified first signal as a fourth signal, a second amplifier disposed on the circuit board and that amplifies the second signal and outputs an amplified second signal as a fifth signal, a combining node that combines the fourth signal and the fifth signal into a combined signal and outputs the combined signal to an output terminal as an output signal, an open stub disposed on the circuit board, the open stub having an end electrically connected to a path between the divider and the first amplifier, and a first impedance converter disposed on the circuit board, the first impedance converter having a first end electrically connected to the second amplifier and a second end electrically connected to the combining node. This allows open stubs to be shortened, and thus allows for miniaturization.
(2) In the above (1), the Doherty amplifier circuit may further include a third amplifier disposed on the circuit board and that amplifies a third signal and outputs an amplified third signal as a sixth signal, and a second impedance converter disposed on the circuit board, the second impedance converter having a first end electrically connected to the third amplifier and a second end electrically connected to the combining node. The divider may divide the input signal into the first signal, the second signal, and the third signal, and the combining node may combine the fourth signal, the fifth signal, and the sixth signal into a combined signal and output the combined signal to the output terminal as the output signal. This allows for miniaturization.
(3) In the above (1) or (2), no impedance converter may be disposed between the first amplifier and the combining node. This allows the phases in the combining node to be aligned.
(4) In any one of the above (1) to (3), the first amplifier may be a main amplifier, and the second amplifier may be a peak amplifier. This allows the bandwidth to be widened.
(5) In any one of the above (1) to (4), the first amplifier and the second amplifier may be arranged in a first direction, the first impedance converter may be disposed adjacent to the second amplifier in a second direction intersecting the first direction, and the open stub may be disposed adjacent to the first amplifier in the first direction. This allows the width of the circuit board in the second direction to be reduced.
(6) In any one of the above (1) to (5), the Doherty amplifier circuit may include a package including the first amplifier and the second amplifier, the package being mounted on the circuit board. The open stub and the first impedance converter may be not included in the package. This allows the first amplifier, the second amplifier, the open stub, and the first impedance converter to be disposed on the circuit board.
(7) In any one of the above (1) to (6), the first impedance converter may be a ¼-wavelength line with respect to a center frequency of an operating band, and the open stub may be a ⅛-wavelength line with respect to the center frequency of the operating band. This allows the phases of the fourth signal and the fifth signal in the combining node to be aligned.
(8) A semiconductor device for a Doherty amplifier circuit according to an embodiment of the present disclosure includes a first input terminal that receives a first signal divided from a received input signal, a second input terminal that receives a second signal divided from the input signal, a first amplifier that amplifies the first signal and outputs an amplified first signal as a fourth signal, a second amplifier that amplifies the second signal and outputs an amplified second signal as a fifth signal, a first output terminal that outputs the fourth signal a second output terminal that outputs the fifth signal, and a terminal connected to a line between the first input terminal and the first amplifier, the terminal being connectable to an open stub that adjusts a phase of the first signal. This allows for miniaturization.
(9) In the above (8), the semiconductor device may further include a third input terminal that receives a third signal divided from the input signal, a third amplifier that amplifies the third signal and outputs an amplified third signal as a sixth signal, and a third output terminal that outputs the sixth signal. This allows for miniaturization.
(10) In the above (8) or (9), the semiconductor device may further include a package including the first amplifier and the second amplifier, the first amplifier and the second amplifier being arranged in a first direction. The first input terminal and the second input terminal may be disposed along a first side of the package, the package including the first side and a second side facing each other in a second direction intersecting the first direction. The first output terminal and the second output terminal may be disposed along the second side of the package, the terminal may be disposed along a third side connecting the first side to the second side, and the first amplifier may be closer to the third side than the second amplifier. This allows the electrical length between the path between the first input terminal and the first amplifier and the open stub.

### Details of Embodiments of Present Disclosure

Specific examples of a Doherty amplifier circuit and a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

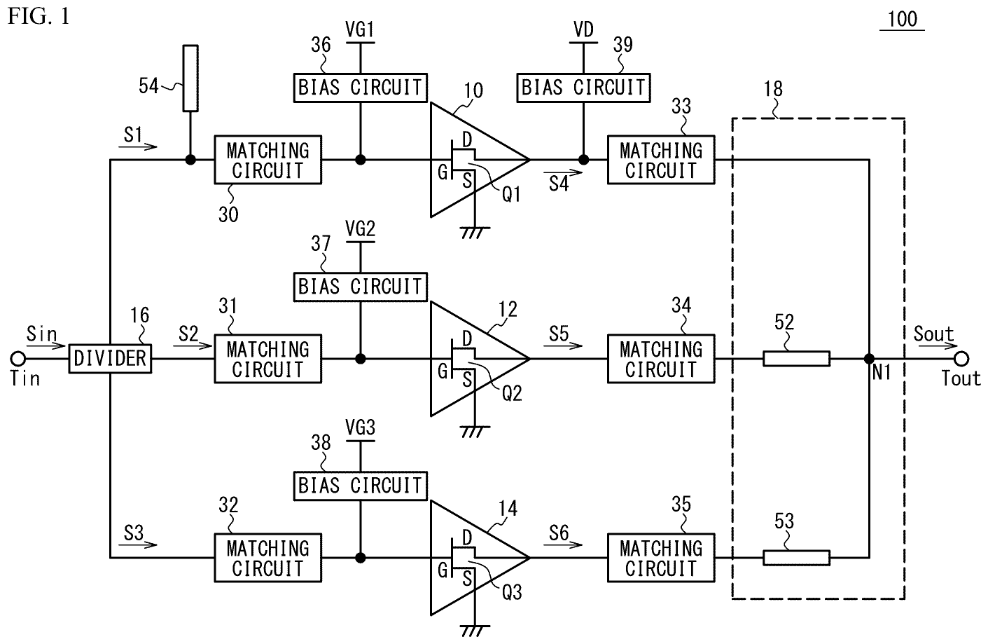

A high-power high-frequency amplifier circuit used in a base station of mobile communication will be described as an example of a Doherty amplifier circuit. In this case, the frequency of the high frequency signal is, for example, 0.5 GHz to 10 GHz. FIG. 1 is a block diagram of a Doherty amplifier circuit according to a first embodiment.

As illustrated in FIG. 1, in a Doherty amplifier circuit 100, a main amplifier 10 (first amplifier), a peak amplifier 12 (second amplifier), and a peak amplifier 14 (third amplifier) are connected in parallel between a divider 16 and a combiner 18. Thus, Doherty amplifier circuit 100 is a 3-way amplifier circuit. The Doherty amplifier circuit may be an N-way Doherty amplifier circuit having one peak amplifier or three or more peak amplifiers.

A high frequency signal is input to an input terminal Tin as an input signal Sin. Divider 16 divides input signal Sin input to input terminal Tin into signals S1 (first signal), S2 (second signal), and S3 (third signal). Divider 16 is, for example, a Wilkinson-type divider.

A path to which signal S1 is input includes an open stub 54, a matching circuit 30, a bias circuit 36, main amplifier 10, a bias circuit 39, and a matching circuit 33. A path to which signal S2 is input includes a matching circuit 31, a bias circuit 37, peak amplifier 12, and a matching circuit 34. A path to which signal S3 is input includes a matching circuit 32, a bias circuit 38, peak amplifier 14, and a matching circuit 35.

Matching circuits 30 to 32 match impedances seen from divider 16 toward matching circuits 30 to 32 to impedances seen from matching circuits 30 to 32 toward main amplifier 10 and peak amplifiers 12 and 14, respectively. Bias circuits 36 to 38 supply gate bias voltages VG1 to VG3 to gates G of main amplifier 10 and peak amplifiers 12 and 14, respectively.

Open stub 54 adjusts the phase of signal S1 in order to adjust the phase of a signal S4 to the phases of signals S5 and S6 which are changed by impedance converters 52 and 53. Open stub 54 is, a transmission line, such as a microstrip line or a coplanar line whose end is open, and is, for example, a ⅛-wavelength line at a center frequency of an operating band.

Main amplifier 10 and peak amplifiers 12 and 14 amplify signals S1, S2 and S3, and output the amplified signals S4 (fourth signal), S5 (fifth signal) and S6 (sixth signal), respectively. Bias circuit 39 supplies a drain bias voltage VD to drains D of main amplifier 10 and peak amplifiers 12 and 14. Matching circuits 33 to 35 match the impedances seen from main amplifier 10 and, peak amplifiers 12 and 14 toward matching circuits 33 to 35, respectively, to the impedances seen from matching circuits 33 to 35 toward combiner 18.

Combiner 18 includes a combining node N1 and impedance converters 52 and 53. Impedance converter 52 has a first end electrically connected to peak amplifier 12 via matching circuit 34 and a second end electrically connected to combining node N1. Impedance converter 53 has a first end electrically connected to peak amplifier 14 via matching circuit 35 and a second end electrically connected to combining node N1. Combining node N1 combines signals S4 to S6 and outputs the combined signal to an output terminal Tout as an output signal Sout.

Impedance converters 52 and 53 convert impedances on the real axis of a Smith chart when seen from matching circuits 34 and 35 toward impedance converters 52 and 53, respectively, into impedances at different positions on the real axis of the Smith chart when seen from impedance converters 52 and 53 toward combining node N1. When peak amplifier 12 is not operated, impedance converter 52 sets an impedance seen from combining node N1 toward peak amplifier 12 to infinity. When peak amplifier 14 is not operated, impedance converter 53 sets an impedance seen from combining node N1 toward peak amplifier 14 to infinity.

Impedance converters 52 and 53 are transmission lines, such as microstrip lines or coplanar lines, and are ¼-wavelength lines at a center frequency of an operating band. An electrical length of the ¼-wavelength line do not have to be exactly ¼ wavelength. The ¼-wavelength line need only have an electrical length that functions as impedance converters 52 and 53. For example, the electrical length of the ¼-wavelength line may be 3/16 wavelength to 5/16 wavelength, or may be 7/32 wavelength to 9/32 wavelength. The impedance on the real axis of the Smith chart do not have to be strictly on the real axis (reactance component is 0). An absolute value of a reactance component of the impedance may be 0.2 times or less or 0.1 times or less of a resistor component.

Main amplifier 10 and peak amplifiers 12 and 14 include transistors Q1 to Q3, respectively. Transistors Q1 to Q3 are, for example, field effect transistors (FETs), such as gallium nitride high electron mobility transistors (GaN HEMTs) or laterally diffused metal oxide semiconductors (LDMOSs). Sources S of transistors Q1 to Q3 are grounded, signals S1 to S3 are input to each of gates G, and signals S4 to S6 are output from each of drains D.

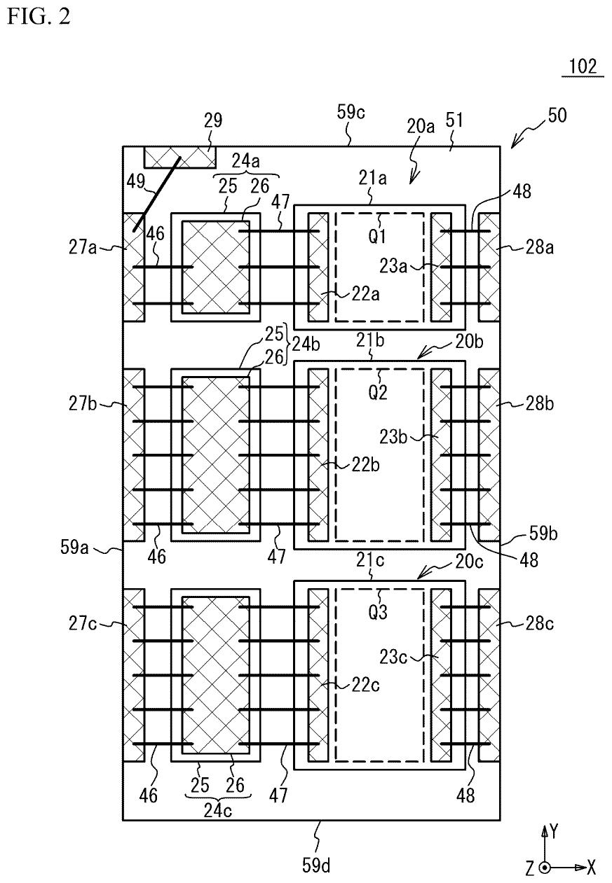

FIG. 2 is a plan view of a semiconductor device in the first embodiment. In FIG. 2, a lid of a package 50 is not illustrated. A thickness direction of a base 51 of package 50 is defined as a Z direction, a direction from leads 27a to 27c toward leads 28a to 28c is defined as an X direction (a second direction intersecting the first direction), and the direction orthogonal to the X direction and the Z direction is defined as a Y direction (a first direction).

As illustrated in FIG. 2, in a semiconductor device 102, package 50 has base 51, at least an upper surface of which is conductive. Base 51 is a conductor substrate, such as a stacked substrate of copper and molybdenum. A reference potential, such as a ground potential, is supplied to base 51. Semiconductor chips 20a to 20c and capacitive components 24a to 24c are mounted on base 51.

Leads 27a to 27c are disposed on a side of base 51 in a negative direction of the X direction with an insulating layer (not illustrated) interposed between base 51 and leads 27a to 27c. Leads 28a to 28c are disposed on a side of base 51 in a positive direction of the X direction. A lead 29 is disposed on a positive side of base 51 in the Y direction with an insulating layer (not illustrated) interposed between base 51 and leads 28a to 28c. Leads 27a to 27c and 28a to 28c are metal layers or metal plates made of, for example, copper. Signals S1 to S3 are input to leads 27a to 27c, respectively, and signals S4 to S6 are output from leads 28a to 28c, respectively.

Semiconductor chip 20a includes a substrate 21a, transistor Q1, pads 22a and 23a disposed on an upper surface of substrate 21a, and an electrode (not illustrated) disposed on a lower surface of substrate 21a. Pads 22a and 23a and the electrode on the lower surface are electrically connected to a gate G (input terminal), a drain D (output terminal), and a source S of transistor Q1, respectively. Semiconductor chip 20b includes a substrate 21b, transistor Q2, pads 22b and 23b disposed on an upper surface of substrate 21b, and an electrode disposed on a lower surface of substrate 21b. Pads 22b and 23b and the electrode on the lower surface are electrically connected to a gate G (input terminal), a drain D (output terminal), and a source S of transistor Q2, respectively. Semiconductor chip 20c includes a substrate 21c, transistor Q3, pads 22c and 23c disposed on an upper surface of substrate 21c, and an electrode disposed on a lower surface of substrate 21c. Pads 22c and 23c and the electrode on the lower surface are electrically connected to a gate G (input terminal), a drain D (output terminal), and a source S of transistor Q3, respectively.

Substrates 21a to 21c are semiconductor substrates. When transistors Q1 to Q3 are GaN HEMTs, substrates 21a to 21c are, for example, silicon carbide (SiC) substrates, sapphire substrates, or gallium nitride (GaN) substrates. When transistors Q1 to Q3 are LDMOS, substrates 21a to 21c are, for example, silicon (Si) substrates. Pads 22a to 22c, 23a to 23c and the electrodes on the lower surfaces are metal layers, such as gold layers. Although transistor Q1 is illustrated as being smaller than transistors Q2 and Q3 (for example, the gate width is smaller and the saturation power is smaller when the gate bias voltage and the drain bias voltage are the same), transistor Q1 may be the same as transistors Q2 and Q3 (for example, the same gate width and the same saturation power when the gate bias voltage and the drain bias voltage are the same).

Each of capacitive components 24a to 24c includes a dielectric substrate 25, an electrode 26 disposed on an upper surface of dielectric substrate 25, and an electrode disposed on a lower surface of dielectric substrate 25. Electrode 26 and the electrode on the lower surface, which sandwich dielectric substrate 25, form a capacitor. Dielectric substrate 25 is, for example, an alumina substrate or a barium titanate substrate. Electrode 26 is a metal layer, such as a gold layer.

Bonding wires 46 electrically connect leads 27a to 27c and electrodes 26 of capacitive components 24a to 24c, respectively. Bonding wires 47 electrically connect electrodes 26 of capacitive components 24a to 24c and pads 22a to 22c, respectively. Bonding wires 48 electrically connect pads 23a to 23c and leads 28a to 28c, respectively. A bonding wire 49 connects lead 27a and lead 29. Bonding wires 46 to 49 are metal wires, such as gold wires or aluminum wires.

Bonding wires 46 and 47 function as inductors, and capacitive components 24a to 24c function as capacitors. Bonding wires 46 and 47 and capacitive components 24a to 24c correspond to matching circuits 30 to 32 of T-type LCL circuits.

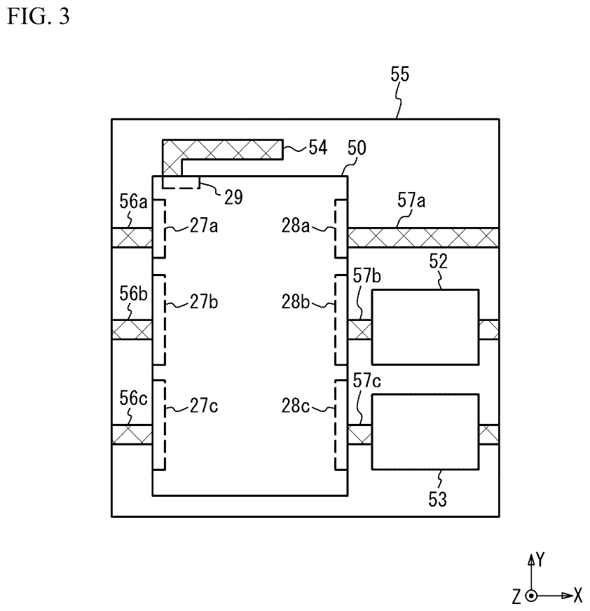

FIG. 3 is a plan view of a circuit board in the first embodiment. As illustrated in FIG. 3, package 50 is mounted on a circuit board 55. Lines 56a to 56c and 57a to 57c, impedance converters 52 and 53, and open stub 54 are disposed on an upper surface of circuit board 55. Circuit board 55 is a resin substrate made of, for example, glass epoxy resin. Lines 56a to 56c, 57a to 57c, impedance converters 52 and 53, and open stub 54 are metal layers such as copper layers.

Lines 56a to 56c are electrically connected to leads 27a to 27c, respectively. Lines 57a to 57c are electrically connected to leads 28a to 28c, respectively. Lines 56a to 56c and 57a to 57c extend in the X direction. Impedance converters 52 and 53 are disposed in the middle of lines 57b and 57c. Impedance converters 52 and 53 are ¼-wavelength lines having a desired characteristic impedance. When the ¼-wavelength line is disposed in a straight line shape, the length is increased. Thus, the ¼-wavelength line is folded and formed like a meander shape. In FIG. 3, the appearance of the folded ¼-wavelength line is illustrated as a rectangle.

An end of open stub 54 is electrically connected to lead 29. Open stub 54 extends in the X direction.

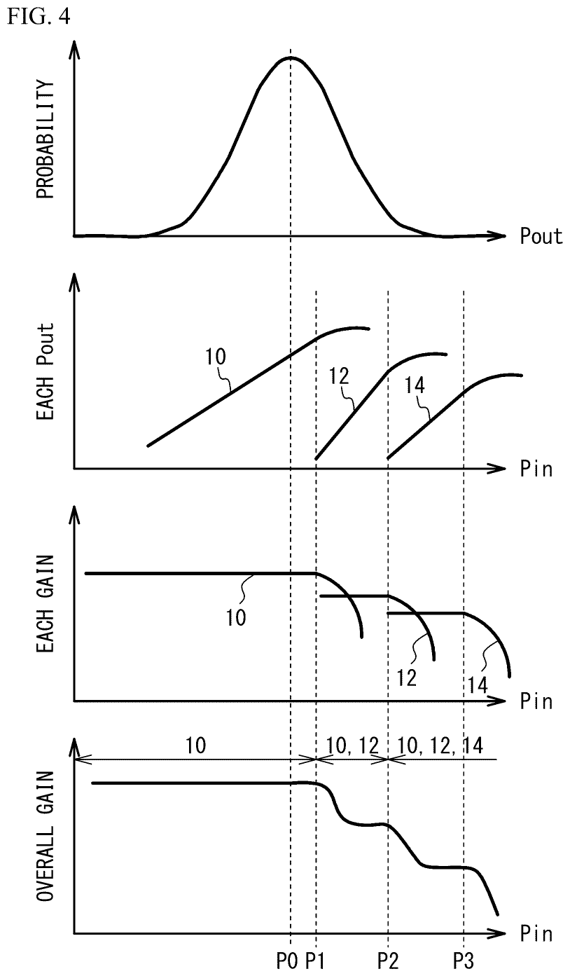

FIG. 4 is a schematic diagram illustrating the probability for Pout, the Pout of each amplifier for Pin, the gain of each amplifier for Pin, and the overall gain for Pin in the first embodiment.

The probability is a probability of a modulated wave signal of a high frequency signal for mobile communication amplified by Doherty amplifier circuit 100. That is, the probability is a probability that Doherty amplifier circuit 100 outputs a certain output power Pout. Each Pout is output power Pout of each of main amplifier 10 and peak amplifiers 12 and 14. Each gain is a power gain of each of main amplifier 10, peak amplifiers 12 and 14. The overall gain is the power gain of output power Pout of output signal Sout with respect to an input power Pin of input signal Sin. Pin and Pout are expressed in dB. The gain of main amplifier 10 at a power P1 or less of each gain is larger than the gain of peak amplifier 12 at power P1 or more and a power P2 or less. That is, the slope of Pout with respect to input power Pin at a power equal to or less than power P1 in main amplifier 10 is larger than the slope of Pout with respect to input power Pin at power P1 or more and power P2 or less in peak amplifier 12. However, FIG. 4 is a schematic diagram, and the slope of Pout with respect to input power Pin at a power equal to or less than power P1 for main amplifier 10 is illustrated to be smaller than the slope of Pout with respect to input power Pin at the power P1 or more and power P2 or less for peak amplifier 12.

As illustrated in FIG. 4, when output power Pout is a power P0, the probability of the modulated wave is the highest. That is, when the signal of the modulated wave is output, the time during which output power Pout is power P0 is the longest. Main amplifier 10 is a class-A or class-AB amplifier, and peak amplifiers 12 and 14 are class-C amplifiers. Input power Pin at which peak amplifier 12 is turned on is larger than input power Pin at which main amplifier 10 is turned on, and input power Pin at which peak amplifier 14 is turned on is larger than input power Pin at which peak amplifier 12 is turned on. This operation can be achieved by making a gate bias voltage VG2 of transistor Q2 negatively larger than a gate bias voltage VG1 of transistor Q1 and making a gate bias voltage VG3 of transistor Q3 negatively larger than gate bias voltage VG2 of transistor Q2.

When input power Pin of input signal Sin increases, at input power Pin more than power P0 and power P1 or less, main amplifier 10 operates, but peak amplifiers 12 and 14 do not operate. When input power Pin is equal to or less than power P1, output power Pout of main amplifier 10 increases linearly as input power Pin increases. Thus, when input power Pin is equal to or less than power P1, each gain and the overall gain are substantially constant.

When input power Pin is equal to or more than power P1 and equal to or less than power P2, main amplifier 10 and peak amplifier 12 operate, but peak amplifier 14 does not operate. In this range, main amplifier 10 is saturated. Thus, the gain of main amplifier 10 is reduced. This also reduces the overall gain. Since peak amplifier 12 is performed in class-C operation, the gain of peak amplifier 12 between power P1 and power P2 is lower than the gain of main amplifier 10 at a power equal to or less than power P1. Also, the saturation power of peak amplifier 12 is smaller than the saturation power of main amplifier 10.

When input power Pin is equal to or more than power P2 and equal to or less than a power P3, all of main amplifier 10 and peak amplifiers 12 and 14 operate. In this range, peak amplifier 12 is saturated in addition to main amplifier 10. Thus, the gain of peak amplifier 12 is reduced. This also reduces the overall gain. Since the operating point of peak amplifier 14 is negatively larger than the operating point of peak amplifier 12, the gain of peak amplifier 14 between powers P2 and P3 is lower than the gain of peak amplifier 12 between powers P1 and P2. Also, the saturation power of peak amplifier 14 is smaller than the saturation power of peak amplifier 12.

When input power Pin is equal to or more than power P3, peak amplifier 14 is saturated in addition to main amplifier 10 and peak amplifier 12. Thus, the gain of peak amplifier 14 is reduced. This also reduces the overall gain.

The product of the probability and the overall gain corresponds to the gain of the modulated wave. In order to improve the gain of the modulated wave, the overall gain at Pout having a high probability is improved.

### First Comparative Example

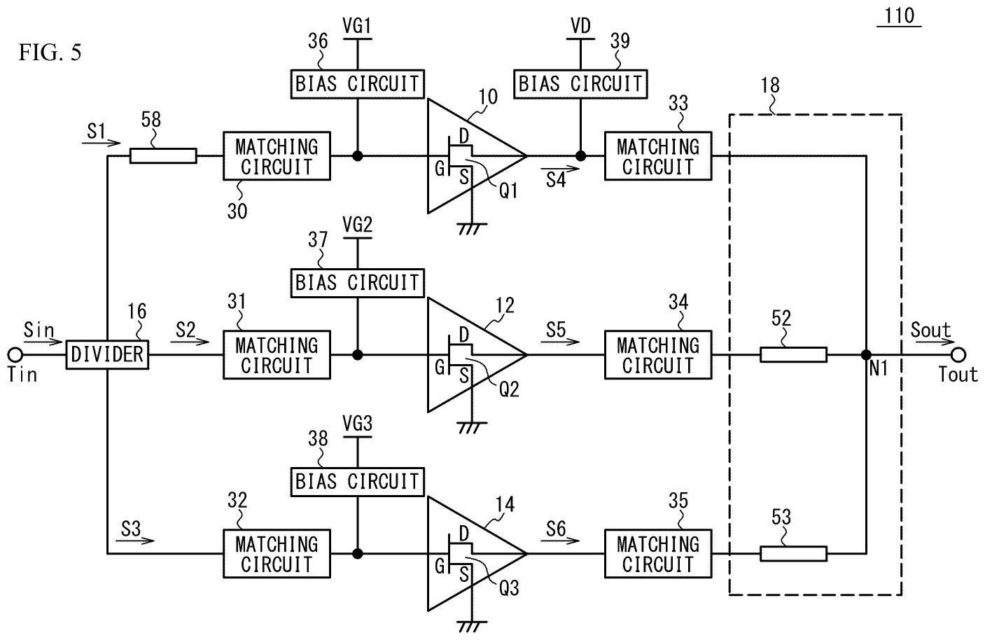

FIG. 5 is a block diagram of a Doherty amplifier circuit in a first comparative example. As illustrated in FIG. 5, in a Doherty amplifier circuit 110 of the first comparative example, a phase adjuster 58 is disposed instead of open stub 54. Phase adjuster 58 is, for example, a ¼-wavelength line. Impedance converters 52 and 53 rotate the phases of signals S5 and S6 by 90°. Thus, phase adjuster 58 is, for example, a ¼-wavelength line.

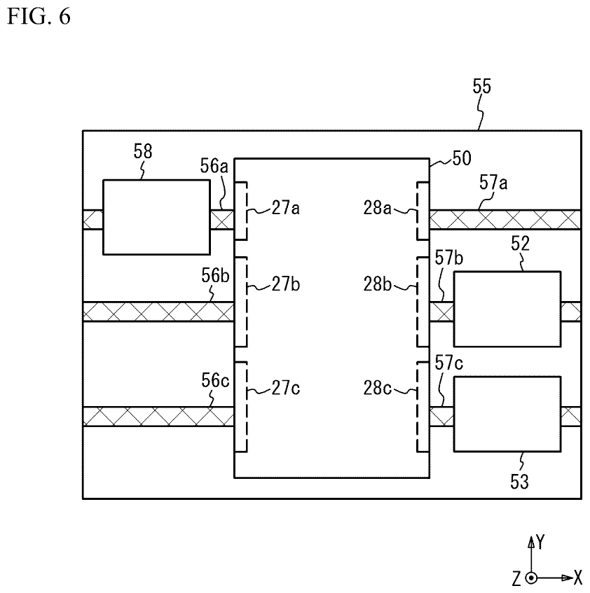

FIG. 6 is a plan view of a semiconductor device in the first comparative example. As illustrated in FIG. 6, in the first comparative example, phase adjuster 58 is disposed in the middle of line 56a instead of open stub 54.

In the Doherty amplifier circuit, in order to appropriately convert the impedances depending on the operation states of main amplifier 10 and peak amplifiers 12 and 14, in combiner 18, impedance converters 52 and 53 are used in either of the paths between main amplifier 10, peak amplifiers 12 and 14, and combining node N1. Impedance converters 52 and 53 are, for example, ¼-wavelength lines, and the phases are rotated by 90°. In combining node N1, when the phases of signals S4 to S6 are not aligned, the overall gain is reduced when input power Pin in FIG. 4 is equal to or more than power P1.

Thus, phase adjuster 58 is disposed in a path in which impedance converters 52 and 53 are not disposed. Thus, combining node N1 combines signals S4 to S6 by aligning the phases of signals S4 to S6. This can improve the overall gain.

However, in order to adjust the phase rotated by 90° in impedance converters 52 and 53, phase adjuster 58 is required to rotate the phase by 90°. Thus, when the ¼-wavelength line is used as phase adjuster 58, the size of the Doherty amplifier circuit increases.

### Description of First Embodiment

In Doherty amplifier circuit 100, the impedances seen from main amplifier 10 and peak amplifiers 12 and 14 toward combining node N1 are properly converted, and when peak amplifiers 12 and 14 do not operate, the impedances seen from combining node N1 toward each of peak amplifiers 12 and 14 are set to infinity. Thus, impedance converter 52 (first impedance converter) having a first end electrically connected to one second amplifier of peak amplifiers 12 and 14 (for example, peak amplifier 12) and a second end electrically connected to combining node N1 is provided. In such a case, as illustrated in FIG. 1, open stub 54 having an end electrically connected to a path between divider 16 and one first amplifier of main amplifier 10 and peak amplifiers 12 and 14 (for example, main amplifier 10) is disposed as a phase adjuster. For example, in order to rotate the phase of signal S1 by 90°, the electrical length of open stub 54 at the center frequency of the operating band is ⅛ wavelength. As a result, as illustrated in FIG. 3, open stub 54 can be shortened, and thus circuit board 55 can be miniaturized. Peak amplifier 14 and impedance converter 53 do not have to be disposed.

The electrical length of the ⅛-wavelength line used as open stub 54 do not have to be exactly ⅛ wavelength with respect to the center frequency of the operating band, and it is sufficient that the phases of signals S4 to S6 can be aligned. The electrical length of the ⅛-wavelength line may be, for example, 3/32 wavelength to 5/32 wavelength, or 7/64 wavelength to 9/64 wavelength.

When two or more peak amplifiers 12 and 14 are disposed, impedance converter 53 (second impedance converter) having a first end electrically connected to one third amplifier of peak amplifiers 12 and 14 (for example, peak amplifier 14) and a second end electrically connected to combining node N1 is disposed. In this case, the phases of signals S5 and S6 are both rotated by 90°. Thus, by disposing open stub 54, the phases of signals S4 to S6 in combining node N1 can be aligned.

No impedance converter is disposed between main amplifier 10 and combining node N1. In this case, by disposing open stub 54, the phases of signals S4 to S6 in combining node N1 can be aligned.

When ¼-wavelength lines are disposed as impedance converters 52 and 53, it is difficult to achieve a wider bandwidth. Thus, in order to widen the bandwidth of main amplifier 10 that is operated at all input power Pin as illustrated in FIG. 4, an impedance converter may not be disposed between main amplifier 10 and combining node N1 as illustrated in FIG. 1. In such a case, open stub 54 is connected between divider 16 and main amplifier 10. Thus, the first amplifier is main amplifier 10, and the second amplifier and the third amplifier are peak amplifiers 12 and 14, respectively.

In the first comparative example, as illustrated in FIG. 6, main amplifier 10 and peak amplifiers 12 and 14 are arranged in the Y direction (first direction). Impedance converters 52 and 53 are disposed in the positive direction of the X direction (the second direction intersecting the first direction) of peak amplifiers 12 and 14, respectively. Phase adjuster 58 is disposed in the negative direction of the X direction of main amplifier 10. Thus, the width of circuit board 55 in the X direction is increased.

In the first embodiment, open stub 54 is disposed in the Y direction of main amplifier 10. This can reduce the width of circuit board 55 in the X direction. Thus, circuit board 55 can be miniaturized. Open stub 54 extends in the X direction. This can reduce the width of circuit board 55 in the Y direction.

As illustrated in FIGS. 2 and 3, main amplifier 10 and peak amplifiers 12 and 14 are mounted on package 50. Open stub 54 and impedance converters 52 and 53 are not mounted on package 50, but are disposed on circuit board 55. Thus, by mounting package 50 on circuit board 55, main amplifier 10, peak amplifiers 12 and 14 can be disposed on circuit board 55, and impedance converters 52 and 53 can be disposed on circuit board 55.

Impedance converters 52 and 53 are ¼-wavelength lines with respect to a center frequency of an operating band. Thus, impedance converters 52 and 53 can convert impedances on the real axis of the Smith chart seen from matching circuits 34 and 35 toward impedance converters 52 and 53 into impedances at different positions on the real axis of the Smith chart seen from the impedance converters 52 and 53 toward the combining node N1. Open stub 54 is a ⅛-wavelength line with respect to the center frequency of the operating band. Thus, the phase of signal S4 can be aligned with the phase of signals S5 and S6 rotated by 90° in impedance converters 52 and 53.

Semiconductor device 102 of FIG. 2 includes lead 27a (first input terminal), lead 27b (second input terminal), lead 27c (third input terminal), lead 28a (first output terminal), lead 28b (second output terminal), and lead 28c (third output terminal). Lead 29 (terminal) is connected to a line between lead 27a and main amplifier 10, and is connectable to open stub 54 to adjust a phase of signal S1. By disposing lead 29 for open stub 54 in package 50, circuit board 55 can be miniaturized as illustrated in FIG. 3.

Package 50 has sides 59a and 59b facing each other in the X direction and sides 59c and 59d facing each other in the Y direction. Leads 27a to 27c are disposed on side 59a (first side), and leads 28a to 28c are disposed on side 59b (second side). Main amplifier 10 is closest to side 59c (third side) connecting sides 59a and 59b among main amplifier 10, peak amplifiers 12 and 14. Lead 29 is disposed on side 59c. This makes it possible to shorten bonding wire 49 connected to lead 29. Thus, the electrical length between open stub 54 and the path between lead 27a and main amplifier 10 can be shortened. The accuracy of the substantial electrical length of open stub 54 can be improved.

Although the 3-way Doherty amplifier circuit has been described as an example, a 2-way Doherty amplifier circuit without peak amplifier 14 and impedance converter 53 may be used. Further, the N-way Doherty amplifier circuit in which N is four or more may be used. In this case, N-1 peak amplifiers may be disposed.

The embodiments disclosed here should be considered illustrative in all respects and not restrictive. The present disclosure is not limited to the specific embodiments described above, but various variations and changes are possible within the scope of the gist of the present disclosure as described in the claims.

1. A Doherty amplifier circuit comprising:
a divider that divides a received input signal into a first signal and a second signal;
a circuit board;
a first amplifier disposed on the circuit board and that amplifies the first signal and outputs an amplified first signal as a fourth signal;
a second amplifier disposed on the circuit board and that amplifies the second signal and outputs an amplified second signal as a fifth signal;
a combining node that combines the fourth signal and the fifth signal into a combined signal and outputs the combined signal to an output terminal as an output signal;
an open stub disposed on the circuit board, the open stub having an end electrically connected to a path between the divider and the first amplifier; and
a first impedance converter disposed on the circuit board, the first impedance converter having a first end electrically connected to the second amplifier and a second end electrically connected to the combining node.

2. The Doherty amplifier circuit according to claim 1, further comprising:
a third amplifier disposed on the circuit board and that amplifies a third signal and outputs an amplified third signal as a sixth signal; and
a second impedance converter disposed on the circuit board, the second impedance converter having a first end electrically connected to the third amplifier and a second end electrically connected to the combining node, wherein
the divider divides the input signal into the first signal, the second signal, and the third signal, and
the combining node combines the fourth signal, the fifth signal, and the sixth signal into a combined signal and output the combined signal to the output terminal as the output signal.

3. The Doherty amplifier circuit according to claim 1, wherein no impedance converter is disposed between the first amplifier and the combining node.

4. The Doherty amplifier circuit according to claim 1, wherein
the first amplifier is a main amplifier, and
the second amplifier is a peak amplifier.

5. The Doherty amplifier circuit according to claim 1, wherein
the first amplifier and the second amplifier are arranged in a first direction,
the first impedance converter is disposed adjacent to the second amplifier in a second direction intersecting the first direction, and
the open stub is disposed adjacent to the first amplifier in the first direction.

6. The Doherty amplifier circuit according to claim 1, further comprising
a package including the first amplifier and the second amplifier, the package being mounted on the circuit board, wherein
the open stub and the first impedance converter are not included in the package.

7. The Doherty amplifier circuit according to claim 1, wherein
the first impedance converter is a ¼-wavelength line with respect to a center frequency of an operating band, and
the open stub is a ⅛-wavelength line with respect to the center frequency of the operating band.

8. A semiconductor device for a Doherty amplifier circuit, the semiconductor device comprising:
a first input terminal that receives a first signal divided from a received input signal;
a second input terminal that receives a second signal divided from the input signal;
a first amplifier that amplifies the first signal and outputs an amplified first signal as a fourth signal;
a second amplifier that amplifies the second signal and outputs an amplified second signal as a fifth signal;
a first output terminal that outputs the fourth signal;
a second output terminal that outputs the fifth signal; and
a terminal connected to a line between the first input terminal and the first amplifier, the terminal being connectable to an open stub that adjusts a phase of the first signal.

9. The semiconductor device according to claim 8, further comprising:
a third input terminal that receives a third signal divided from the input signal;
a third amplifier that amplifies the third signal and outputs an amplified third signal as a sixth signal; and
a third output terminal that outputs the sixth signal.

10. The semiconductor device according to claim 8, further comprising
a package including the first amplifier and the second amplifier, the first amplifier and the second amplifier being arranged in a first direction, wherein
the first input terminal and the second input terminal are disposed along a first side of the package, the package including the first side and a second side facing each other in a second direction intersecting the first direction,
the first output terminal and the second output terminal are disposed along the second side of the package,
the terminal is disposed along a third side connecting the first side to the second side, and
the first amplifier is closer to the third side than the second amplifier.
